(19) United States
(12) Patent Application Publication
(10) Pub. No.: US 2025/0169368 A1
(43) Pub. Date: May 22, 2025

(54) METHOD FOR FORMING A SEMICONDUCTOR STRUCTURE

(71) Applicant: UNITED MICROELECTRONICS CORP., Hsin-Chu City (TW)

(72) Inventors: Chau-Chung Hou, Kaohsiung City (TW); Kun-Ju Li, Tainan City (TW); Hsin-Jung Liu, Pingtung County (TW); Ching-Hua Hsu, Kaohsiung City (TW); Chen-Yi Weng, New Taipei City (TW); Chih-Yueh Li, Taipei City (TW); Hsin-Kuo Hsu, Kaohsiung City (TW); Ying-Chu Chen, Changhua County (TW); Yi-Chen Hsiao, Tainan City (TW)

(73) Assignee: UNITED MICROELECTRONICS CORP., Hsin-Chu City (TW)

(21) Appl. No.: 18/407,360

(22) Filed: Jan. 8, 2024

(30) Foreign Application Priority Data
Nov. 21, 2023 (TW) 112144878

(51) Int. Cl. H10N 50/01; G11C 11/16; H10B 61/00; H10N 50/80

(52) U.S. Cl. CPC H10N 50/01; H10B 61/00; H10N 50/80; G11C 11/161

(57) ABSTRACT

A method of forming a semiconductor structure is disclosed. A substrate is provided having a memory array area and a peripheral region. A memory structure is formed on the substrate in the memory array area. A step height is formed between the memory array area and the peripheral region. A dielectric layer is deposited. The dielectric layer covers the memory structure. A reverse etching process is performed to remove part of the dielectric layer from the memory array area, thereby forming an upwardly protruding wall structure along the perimeter of the memory array area, wherein the thickness of the dielectric layer in the memory array area increases from the central area of the memory array area to the periphery of the memory array area. A polishing process is performed on the dielectric layer to remove the upwardly protruding wall structure from the memory array area.

### BACKGROUND OF THE INVENTION

### 1. Field of the Invention

The present invention relates to the field of semiconductor technology, and in particular, to an improved method for manufacturing a semiconductor structure.

### 2. Description of the Prior Art

Magnetoresistive Random Access Memory (MRAM) is a type of non-volatile random-access memory which stores data in magnetic domains. Data in MRAM is stored by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. This configuration is known as a magnetic tunnel junction and is the simplest structure for an MRAM bit.

The fabrication process for forming MRAM cells is usually performed at the metallization back-end stage. The subsequently deposited dielectric layer typically forms a step height between the memory array region and the peripheral circuit area. In order to eliminate such a height difference, a reverse etching process is typically performed after depositing the dielectric layer to first remove part of the dielectric layer located in the memory area, and then a chemical mechanical polishing (CMP) process is performed. However, the above-mentioned prior art method will cause scratches on the surface of the dielectric layer, resulting in metal bridge defects when subsequent metal layers are filled in, which reduces the process yield.

### SUMMARY OF THE INVENTION

It is one object of the present invention to provide an improved method for forming a semiconductor structure in order to solve the above-mentioned shortcomings or deficiencies of the prior art.

One aspect of the invention provides a method for forming a semiconductor structure. A substrate having a memory array region and a peripheral region thereon is provided. A memory structure is formed on the substrate within the memory array region, wherein a step height is formed between the memory array region and the peripheral region. A dielectric layer is deposited over the memory array region and the peripheral region in a blanket manner, wherein the dielectric layer covers the memory structure. A reverse etching process is performed to remove a portion of the dielectric layer from the memory array region, thereby forming an upwardly protruding wall structure along a perimeter of the memory array region, wherein a thickness of the dielectric layer within the memory array region increases from a central area of the memory array region to the perimeter of the memory array region. The dielectric layer is subjected to a polishing process to remove the upwardly protruding wall structure from the memory array region.

According to some embodiments, the dielectric layer comprises a low-k or ultra-low k dielectric material layer.

According to some embodiments, before performing the reverse etching process, the dielectric layer has a top surface within the memory array region that is higher than a top surface of the dielectric layer within the peripheral region.

According to some embodiments, after subjecting the dielectric layer to the polishing process, a remaining thickness of the dielectric layer within the memory array region is 500-800 angstroms.

According to some embodiments, the memory structure comprises a conductive via embedded in a first intermediate dielectric layer, a memory storage structure embedded in a second intermediate dielectric layer, and a protective layer covering a sidewall of the memory storage structure and the first intermediate dielectric layer.

According to some embodiments, the memory storage structure comprises a magnetic tunneling junction (MTJ) structure situated directly on the conductive via.

According to some embodiments, the conductive via comprises a tungsten via.

According to some embodiments, the first intermediate dielectric layer extends into the peripheral region.

According to some embodiments, the dielectric layer is in direct contact with the first intermediate dielectric layer within the peripheral region.

According to some embodiments, the method further includes the step of subjecting the upwardly protruding wall structure to an etching process to form through channels in the upwardly protruding wall structure, thereby dividing the upwardly protruding wall structure into a plurality of islands disposed along the perimeter of the memory array region.

Another aspect of the invention provides a method for forming a semiconductor structure. A substrate having a memory array region and a peripheral region thereon is provided. A memory structure is formed on the substrate within the memory array region, wherein a step height is formed between the memory array region and the peripheral region. A dielectric layer is deposited over the memory array region and the peripheral region in a blanket manner, wherein the dielectric layer covers the memory structure. A reverse etching process is performed to remove a portion of the dielectric layer from the memory array region, thereby forming an upwardly protruding wall structure along a perimeter of the memory array region. The upwardly protruding wall structure is subjected to an etching process to form through channels in the upwardly protruding wall structure, thereby dividing the upwardly protruding wall structure into a plurality of islands disposed along the perimeter of the memory array region. The dielectric layer is subjected to a polishing process to remove the plurality of islands.

According to some embodiments, the dielectric layer comprises a low-k or ultra-low k dielectric material layer.

According to some embodiments, before performing the reverse etching process, the dielectric layer has a top surface within the memory array region that is higher than a top surface of the dielectric layer within the peripheral region.

According to some embodiments, after subjecting the dielectric layer to the polishing process, a remaining thickness of the dielectric layer within the memory array region is 500-800 angstroms.

According to some embodiments, the memory structure comprises a conductive via embedded in a first intermediate dielectric layer, a memory storage structure embedded in a second intermediate dielectric layer, and a protective layer covering a sidewall of the memory storage structure and the first intermediate dielectric layer.

According to some embodiments, the memory storage structure comprises a magnetic tunneling junction (MTJ) structure situated directly on the conductive via.

According to some embodiments, he conductive via comprises a tungsten via.

According to some embodiments, the first intermediate dielectric layer extends into the peripheral region.

According to some embodiments, the dielectric layer is in direct contact with the first intermediate dielectric layer within the peripheral region.

According to some embodiments, the upwardly protruding wall structure has a width of 0.2-0.3 micrometers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 illustrate a method of forming a semiconductor structure in accordance with one embodiment of the present invention.

FIG. 4 to FIG. 7 illustrate another method of forming a semiconductor structure.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

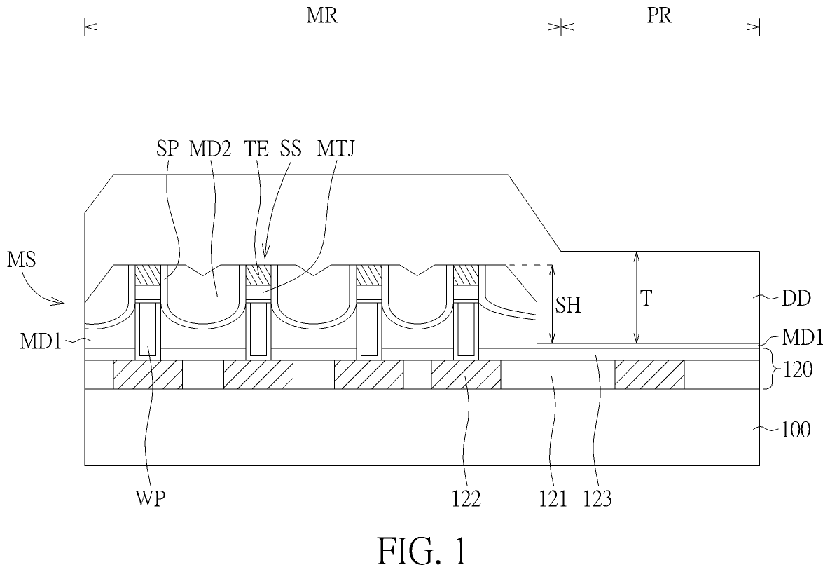

Please refer to FIG. 1 to FIG. 3, which illustrate a method of forming a semiconductor structure in accordance with one embodiment of the present invention. As shown in FIG. 1, a substrate 100 is provided. For example, the substrate 100 may be a silicon substrate, but is not limited thereto. According to an embodiment of the present invention, the substrate 100 has a memory array region MR and a peripheral region (or peripheral circuit region) PR. According to an embodiment of the present invention, a metal interconnect structure 120 may be formed on the substrate 100. According to an embodiment of the present invention, the metal interconnect structure 120 may include, but is not limited to, an inter-metal dielectric layer 121, a conductive layer 122 embedded in the inter-metal dielectric layer 121, and a capping layer 123 covering the planarized inter-metal dielectric layer 121 and the conductive layer 122.

According to an embodiment of the present invention, the conductive layer 122 may be, for example, a second metal layer (M2). According to an embodiment of the present invention, the conductive layer 122 may be, for example, a damascened copper metal layer, and the capping layer 123 may be a nitrogen-doped silicon carbide (NDC) layer, but is not limited thereto. Those skilled in the art should understand that the metal interconnect structure 120 can be electrically connected to transistor elements in or on the substrate 100. For the sake of simplicity, the details of these transistor elements are not shown in the figures.

Subsequently, a memory structure MS is formed on the substrate 100 in the memory array region MR. A step height SH is formed between the memory array region MR and the peripheral region PR. For example, the step height SH may be between 1000-1700 angstroms, but not limited thereto. According to an embodiment of the present invention, the memory structure MS includes a first intermediate dielectric layer MD1, a second intermediate dielectric layer MD2, a conductive via WP embedded in the first intermediate dielectric layer MD1, a memory storage structure SS embedded in the second intermediate dielectric layer MD2, and a protective layer SP covering a sidewall of the memory storage structure SS and the first intermediate dielectric layer MD1. According to an embodiment of the present invention, the first intermediate dielectric layer MD1 may extend onto the peripheral region PR.

According to an embodiment of the present invention, the conductive via WP includes, for example, a tungsten via. According to an embodiment of the present invention, the memory storage structure SS includes a magnetic tunnel junction structure MTJ directly located on the conductive via WP and a top electrode TE directly located on the magnetic tunnel junction structure MTJ.

Subsequently, a dielectric layer DD is deposited over the memory array region MR and the peripheral region PR in a blanket manner. The dielectric layer DD covers the memory structure MS. According to an embodiment of the present invention, for example, the dielectric layer DD may include a low-k dielectric material layer or an ultra-low-k dielectric material layer, but is not limited thereto. According to an embodiment of the present invention, for example, the thickness T of the dielectric layer DD may be 1900-2900 angstroms. According to the embodiment of the present invention, the dielectric layer DD is in direct contact with the first intermediate dielectric layer MD1 in the peripheral region PR. At this point, the top surface of the dielectric layer DD in the memory array region MR is higher than the top surface of the dielectric layer DD in the peripheral region PR.

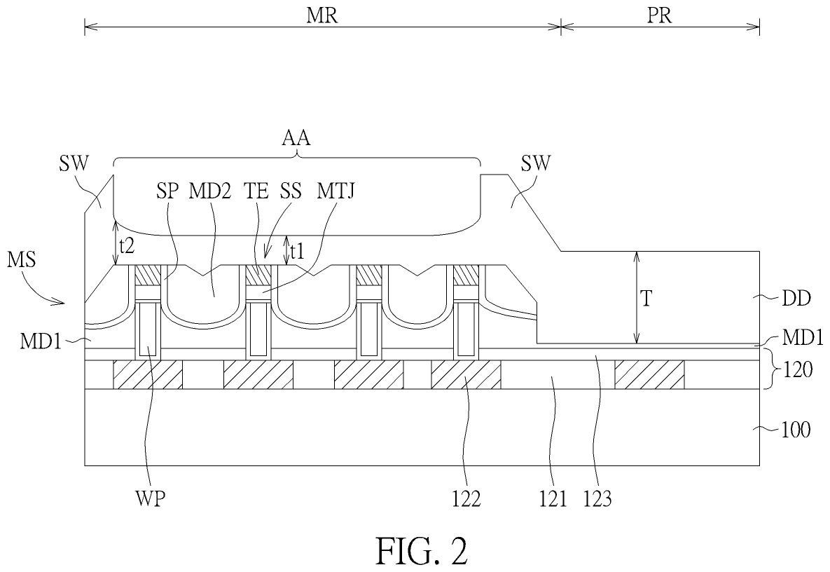

As shown in FIG. 2, a reverse etching process is then performed to remove a portion of the dielectric layer DD from the central area AA of the memory array region MR, thereby forming an upwardly protruding wall structure SW along a perimeter of the memory array region MR. By adjusting the etching parameters, the thickness of the dielectric layer DD in the memory array region MR can be gradually increased from the central area AA of the memory array region MR to the periphery of the memory array region MR (for example, increase from the thickness t1 in the figure to thickness t2).

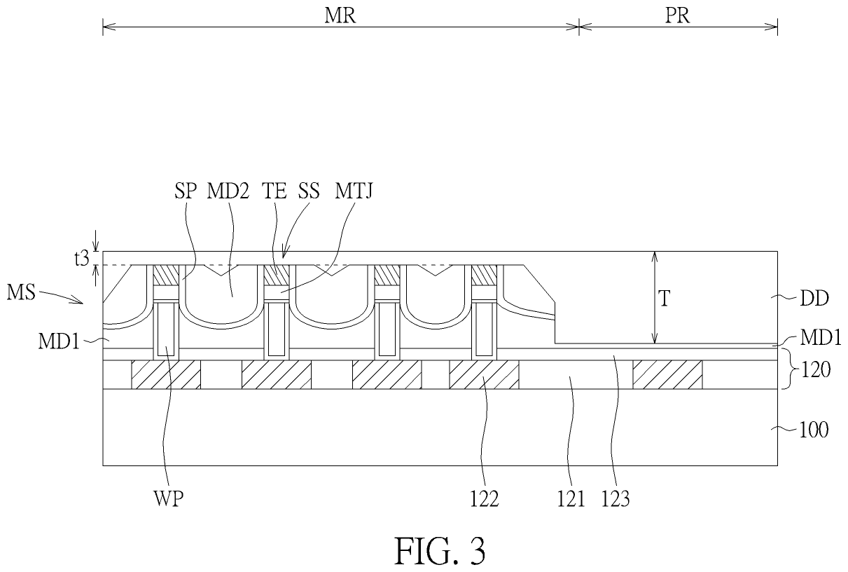

As shown in FIG. 3, a polishing process is performed on the dielectric layer DD to remove the upwardly protruding wall structure SW from the memory array region MR. At this point, the top surface of the dielectric layer DD in the memory array region MR is flush with the top surface of the dielectric layer DD in the peripheral region PR. After the polishing process is performed on the dielectric layer DD, the remaining thickness t3 of the dielectric layer DD in the memory array region MR is about 500-800 angstroms, for example, 650 angstroms. Subsequently, the metal interconnection structure of the next layer can be continued, for example, the third metal layer (M3). Since the metal interconnection process is a well-known technique, it will not be described in detail.

By adjusting the etching parameters in the reverse etching process, the thickness of the dielectric layer DD in the etched memory array region MR is increased from the central area AA of the memory array region MR to the periphery of the memory array region MR. Therefore, in the subsequent polishing process, the upwardly protruding wall structure SW can be effectively removed without causing scratches on the dielectric layer DD.

According to an embodiment of the present invention, before performing the polishing process, an optional etching process can be performed on the upwardly protruding wall structure SW to form a through channel in the upwardly protruding wall structure SW, thereby dividing the upwardly protruding wall structure SW into a plurality of islands disposed along the perimeter of the memory array region MR (details will be described later).

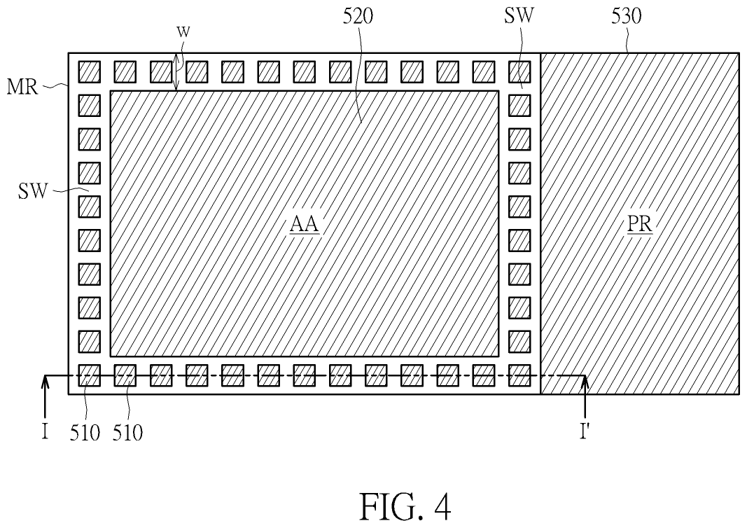

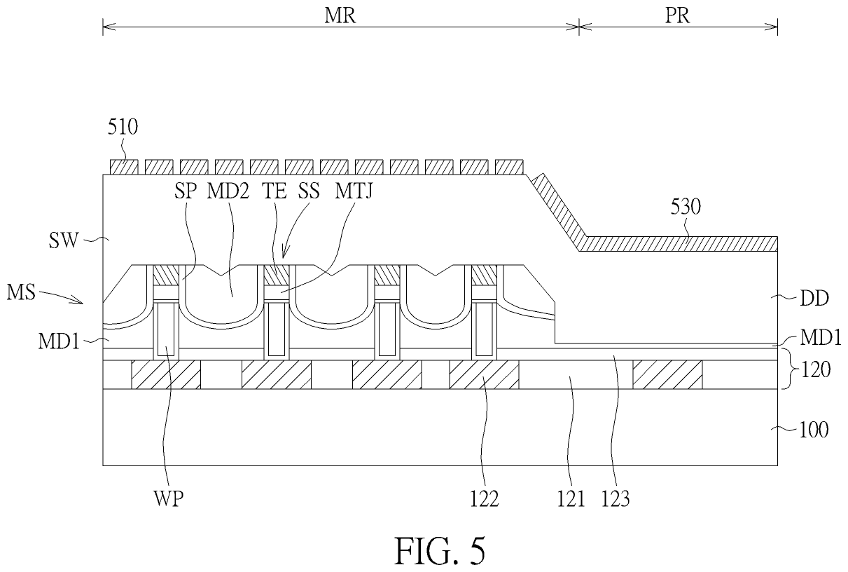

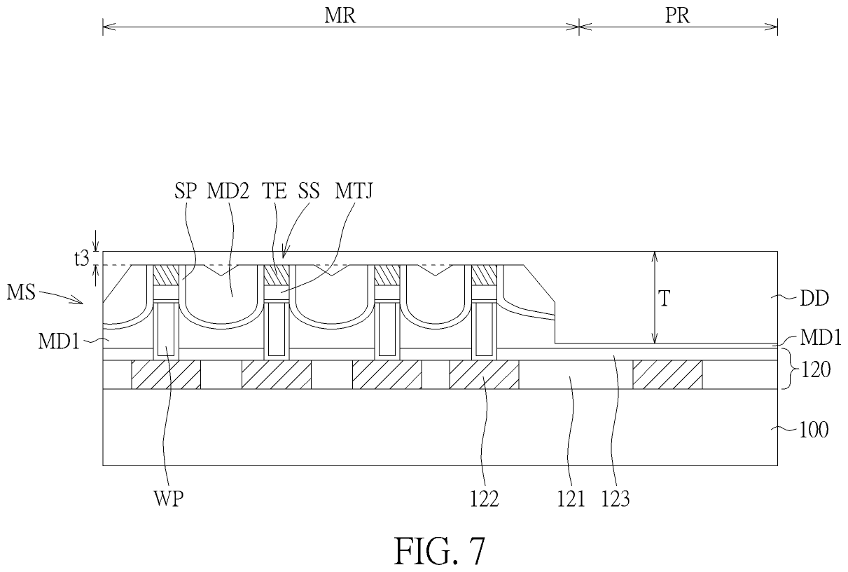

FIG. 4 to FIG. 7 illustrate another method of forming a semiconductor structure. FIG. 4 is a partial top view of the semiconductor structure. FIG. 5 to FIG. 7 are views taken along line I-I′ in FIG. 4. Like areas, layers, or elements are designated by like numeral numbers or labels. As shown in FIG. 4 and FIG. 5, after completing the reverse etching process as set forth in FIG. 2, an upwardly protruding wall structure SW is formed along the perimeter of the memory array region MR. According to an embodiment of the present invention, the width w of the upwardly protruding wall structure SW is about 0.2-0.3 micrometers, for example, 0.25 micrometers. A photolithography process is then performed to form a plurality of island-shaped photoresist patterns 510 on the top surface of the upwardly protruding wall structure SW along the perimeter of the memory array region MR. At this point, the central area AA of the memory array area MR is covered by the photoresist pattern 520, and the peripheral region PR is covered by the photoresist pattern 530.

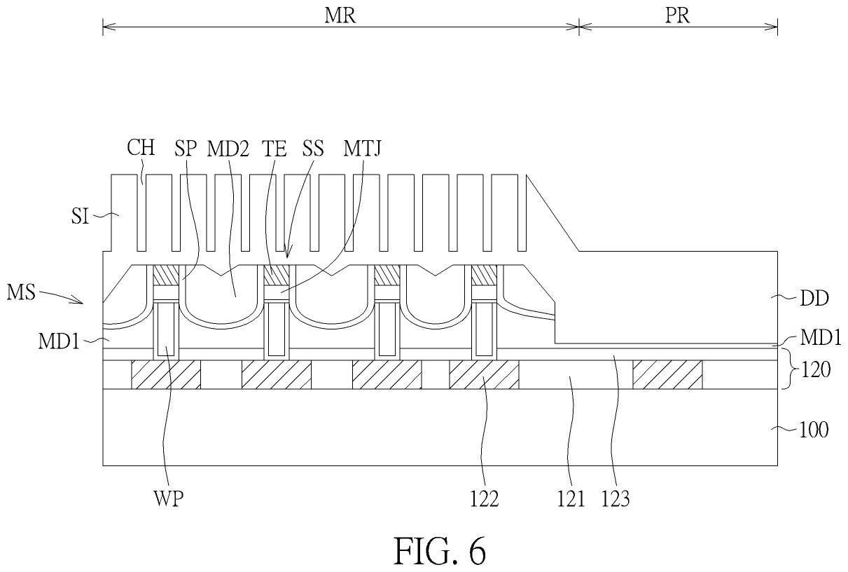

As shown in FIG. 6, the upwardly protruding wall structure SW is then subjected to an etching process, such as an anisotropic dry etching process, to form through channels CH in the upwardly protruding wall structure SW, thereby dividing the upwardly protruding wall structure SW into a plurality of islands SI arranged along the perimeter of the memory array region MR. According to an embodiment of the present invention, for example, the depth of the through channel CH is about 1200-1600 angstroms, but is not limited thereto. According to the embodiment of the present invention, the through channels CH connect the central area AA of the memory array region MR and the peripheral region PR.

Subsequently, a polishing process is performed on the dielectric layer DD to remove the islands SI from the memory array region MR. At this point, the top surface of the dielectric layer DD in the memory array region MR is flush with the top surface of the dielectric layer DD in the peripheral region PR. After removing the islands SI, the remaining thickness t3 of the dielectric layer DD in the memory array region MR is about 500-800 angstroms, for example, 650 angstroms. Subsequently, the metal interconnection structure of the next layer can be continued, for example, the third metal layer (M3). Since the metal interconnection process is a well-known technique, it will not be described in detail.

It is advantageous to use the present invention because the upwardly protruding wall structure SW is divided into a plurality of islands SI arranged along the perimeter of the memory array region MR. The through channels CH between the islands SI can help make the removal of the islands SI during the subsequent chemical mechanical polishing process easier, without causing scratches on the dielectric layer DD.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a semiconductor structure, comprising:
providing a substrate having a memory array region and a peripheral region thereon;
forming a memory structure on the substrate within the memory array region, wherein a step height is formed between the memory array region and the peripheral region;
blanketly depositing a dielectric layer over the memory array region and the peripheral region, wherein the dielectric layer covers the memory structure;
performing a reverse etching process to remove a portion of the dielectric layer from the memory array region, thereby forming an upwardly protruding wall structure along a perimeter of the memory array region, wherein a thickness of the dielectric layer within the memory array region increases from a central area of the memory array region to the perimeter of the memory array region; and
subjecting the dielectric layer to a polishing process to remove the upwardly protruding wall structure from the memory array region.

2. The method according to claim 1, wherein the dielectric layer comprises a low-k or ultra-low k dielectric material layer.

3. The method according to claim 1, wherein before performing the reverse etching process, the dielectric layer has a top surface within the memory array region that is higher than a top surface of the dielectric layer within the peripheral region.

4. The method according to claim 1, wherein after subjecting the dielectric layer to the polishing process, a remaining thickness of the dielectric layer within the memory array region is 500-800 angstroms.

5. The method according to claim 1, wherein the memory structure comprises a conductive via embedded in a first intermediate dielectric layer, a memory storage structure embedded in a second intermediate dielectric layer, and a protective layer covering a sidewall of the memory storage structure and the first intermediate dielectric layer.

6. The method according to claim 5, wherein the memory storage structure comprises a magnetic tunneling junction (MTJ) structure situated directly on the conductive via.

7. The method according to claim 5, wherein the conductive via comprises a tungsten via.

8. The method according to claim 5, wherein the first intermediate dielectric layer extends into the peripheral region.

9. The method according to claim 8, wherein the dielectric layer is in direct contact with the first intermediate dielectric layer within the peripheral region.

10. The method according to claim 1 further comprising:
subjecting the upwardly protruding wall structure to an etching process to form through channels in the upwardly protruding wall structure, thereby dividing the upwardly protruding wall structure into a plurality of islands disposed along the perimeter of the memory array region.

11. A method for forming a semiconductor structure, comprising:
providing a substrate having a memory array region and a peripheral region thereon;
forming a memory structure on the substrate within the memory array region, wherein a step height is formed between the memory array region and the peripheral region;
blanketly depositing a dielectric layer over the memory array region and the peripheral region, wherein the dielectric layer covers the memory structure;
performing a reverse etching process to remove a portion of the dielectric layer from the memory array region, thereby forming an upwardly protruding wall structure along a perimeter of the memory array region;
subjecting the upwardly protruding wall structure to an etching process to form through channels in the upwardly protruding wall structure, thereby dividing the upwardly protruding wall structure into a plurality of islands disposed along the perimeter of the memory array region; and
subjecting the dielectric layer to a polishing process to remove the plurality of islands.

12. The method according to claim 11, wherein the dielectric layer comprises a low-k or ultra-low k dielectric material layer.

13. The method according to claim 11, wherein before performing the reverse etching process, the dielectric layer has a top surface within the memory array region that is higher than a top surface of the dielectric layer within the peripheral region.

14. The method according to claim 11, wherein after subjecting the dielectric layer to the polishing process, a remaining thickness of the dielectric layer within the memory array region is 500-800 angstroms.

15. The method according to claim 11, wherein the memory structure comprises a conductive via embedded in a first intermediate dielectric layer, a memory storage structure embedded in a second intermediate dielectric layer, and a protective layer covering a sidewall of the memory storage structure and the first intermediate dielectric layer.

16. The method according to claim 15, wherein the memory storage structure comprises a magnetic tunneling junction (MTJ) structure situated directly on the conductive via.

17. The method according to claim 15, wherein the conductive via comprises a tungsten via.

18. The method according to claim 15, wherein the first intermediate dielectric layer extends into the peripheral region.

19. The method according to claim 18, wherein the dielectric layer is in direct contact with the first intermediate dielectric layer within the peripheral region.

20. The method according to claim 11, wherein the upwardly protruding wall structure has a width of 0.2-0.3 micrometers.
